(19) United States
(12) Patent Application Publication
(10) Pub. No.: US 2026/0105952 A1
(43) Pub. Date: Apr. 16, 2026

(54) Independent Reference Generation for Single RBL Memory Circuits

(71) Applicants: Raaam Memory Technologies Ltd, Petach Tikva (IL); Bar Ilan University, Ramat Gan (IL)

(72) Inventors: Halil Andac YIGIT, Ecublens (CH); Robert GITERMAN, LAUSANNE (CH); Andreas BURG, ECHANDENS-DENGES (CH); Adam TEMAN, Petach Tikva (IL); Odem HAREL, Yehud (IL)

(21) Appl. No.: 19/350,372

(22) Filed: Oct. 6, 2025

Related U.S. Application Data
(60) Provisional application No. 63/706,689, filed on Oct. 13, 2024.

(51) Int. Cl. G11C 11/4091; G11C 11/4094; G11C 11/4096

(52) U.S. Cl. CPC G11C 11/4091; G11C 11/4094; G11C 11/4096

(57) ABSTRACT

There is provided a memory array which includes a two reference bitcells reference bitcell for each column of the array. The reference bitcells are used to generate a reference level for memory architectures in which the inverted version of the RBL is not available. The reference bitcells store opposite constant logic levels. Reference bitcells in adjacent rows store opposite constant logic levels. When a word is read from memory, one side of the memory array is read and the levels are determined by comparison with the output of the reference bitcell on the opposite side of the array. The side of the array that is read for any given read operation is determined by a predetermined bit in the address. Two rows of switching elements connect the read bitlines of either the row of first reference bitcells or the row of second reference bitcells together.

### CROSS REFERENCE TO RELATED APPLICATIONS

This application claims the benefit of priority of U.S. Provisional Patent Application No. 63/706,689, filed Oct. 13, 2024, the contents of which are incorporated herein by reference in their entirety.

### TECHNICAL FIELD

The present disclosure, in some embodiments, thereof, relates to memory arrays and, more particularly, but not exclusively, to generating reference levels for read operations in a memory array.

### BACKGROUND

In memory circuits one of the main operations is the read operation. During this operation, the stored bitcell level is translated as Read Bit Line (RBL) current or voltage into an analog signal, which is then converted into a digital output value (“1” or “0”) at the comparator stage (e.g. by sense amplifiers). For the comparison operation, two inputs are required at the sense amplifiers.

In two RBL memory array architecture (such as standard SRAM), the RBL and its inverted version (RBLb) are used as inputs to the sense amplifier. However, for most of the high area-efficient memory architectures (such as DRAM and GC-eDRAM) the inverted version of the RBL (RBLb) is not available. In these types of circuits, the RBL output level is compared with a reference level (REF) to determine the output. Many of the previously proposed solutions require an externally supplied reference voltage, which requires significant area and suffers from reliability issues since they lack the ability to track the evaluation of RBL over the time of read cycle and are therefore more sensitive to PVT and delay variations.

### SUMMARY OF THE INVENTION

According to some embodiments of the disclosure, there are provided a memory array, a memory macro and a method with internal reference level generation.

One challenge in dynamic memory design is the finite data retention time (DRT), which necessitates refresh cycles that consume power and limit memory availability. Subthreshold, gate and junction leakages, as well as coupling capacitance, all cause degradation of the charge stored inside the bitcell. Moreover, Process-Voltage-Temperature (PVT) variations result in a large distribution of the read bit line (RBL) voltage further complicating the read phase. Unlike SRAM, which has a complimentary bit-line for reading, some bitcells provide only a single RBL signal to the sense amplifier which samples the data for the output. Therefore, a reference voltage is often utilized for comparing the RBL voltage using a differential sense amplifier (DSA).

Examples of single RBL bitcells suitable for embodiments of the disclosure include but are not limited to:
i. Single ported static random-access memory (SRAM);
ii. Dynamic random-access memory (DRAM);
iii. 1T-1C embedded DRAM (eDRAM); and
iv. Gain-Cell RAM (GCRAM).

Other technically suitable bitcells may be currently known or developed in the future, and the term “bitcell” is intended to include all such types of bitcells.

For purposes of clarity, as used herein the term “row of an array” indicates bitcells which store a data word and the term “column of an array” indicates parallel bitcells from multiple rows in the array. A column may include additional bitcells which are used to support memory array functionality, such as the reference bitcells described herein. The terms row and column are not intended to indicate any physical orientation of the memory array.

Generating the REF signal is a challenging task because this REF significantly affects the yield and needs to be calibrated according to process, voltage, and temperature (PVT) variations to maintain high yield. Moreover, read operations generally involve charging and discharging processes, which are time dependent. To maximize yield, it is desired that the generated reference should also be time-dependent and should follow the stored bit characteristics. It is also beneficial for the reference voltage to track the difference in the evaluation of RBL for ‘1’ and ‘0’ data levels.

Embodiments according to the disclosure provide a technical solution to the technical problem of generating a reference signal which maximizes DRT, while tracking both PVT variations and coupling capacitance. The technical solution to this technical problem is to generate the reference level internally, by adding at least one pair of reference rows within the memory array. Each pair of reference rows includes two reference bitcells for each memory array column. In each column, the two reference bitcells store opposite data levels. The data level stored in each reference bitcell remains constant during memory array operation. In other words, data level ‘0’ is repeatedly written to one of the reference bitcells and data level ‘1’ is repeatedly written to the other reference bitcell.

A used herein, according to some embodiments of the disclosure, the term “data bitcell” should be expansively construed to cover a bitcell configured to store a data level of a word being written to and accessed from the memory array and having a single RBL. A used herein, according to some embodiments of the disclosure, the term “reference bitcell” should be expansively construed to cover a bitcell configured to provide a reference level when a read operation is being performed on the memory array.

The reference bitcells separate the bits in a given row into two segments. The read operation is performed separately for each segment. When one segment is being accessed, the reference bitcell on the opposite side is enabled. The reference bitcell discharges to one side of the row while the enabled reference bitcell discharges to the opposite side of the row and serves as a reference signal to the sense amplifier.

According to some embodiments of the disclosure, the reference bitcells are organized in a braided form for a symmetrical layout structure, and their values are fixed (“1” or “0”). This arrangement allows for a higher yield during read operations.

Using this memory structure and operation the internally generated dynamic reference signal(s) (i.e. the reference level from the respective reference bitcell) follow the same variations as the RBL voltage from the data storage bitcells to which they are compared.

Some embodiments of the disclosure include at least one of:
Using the same bitcell structure for the reference bitcells as for the bitcells used for data storage to mimic bitcell variations.
Utilizing the same timed signal for the reference bitcells as for the bitcells used for data storage to mimic charging and discharging operations.
Connecting a similar load to the reference bitcells as to the bitcells used for data storage to match the charging and discharging behavior.
Using the same read and write signals for the reference bitcells as for the bitcells used for data storage to mimic the coupling effect.
Utilizing separate bit-line characteristics to maximize frequency and word-length.
Optimizing the layout of the memory array so the reference rows provide for coverage of all bit-cells while consuming minimal surface area.
Using RBL lines that are currently not being accessed to minimize local variations of the reference level.

According to a first aspect of some embodiments of the present disclosure there is provided memory array which includes:
an array comprising a plurality of bitcells arranged in rows and columns, each of the rows storing a respective data word, wherein each of the columns respectively comprises:
   a first subset of the bitcells, configured for storing a first subset of data bits, wherein a first read bitline is connected to respective read bitline inputs of the first subset of bitcells;
   a second subset of the bitcells, configured for storing a second set of data bits, wherein a second read bitline is connected to respective read bitline inputs of the second subset of bitcells;
   a first reference bitcell having a read bitline input connected to the second read bitline and configured for storing a first reference data level; and
   a second reference bitcell having a read bitline input connected to the first read bitline and configured for storing a second reference data level,
   wherein each of the bitcells is further connected to a respective word line configured to trigger a read operation of the respective bitcell;
the first reference bitcells of the columns and the second reference bitcells of the columns respectively comprising a first reference bitcell row of the array and a second reference bitcell row of the array, wherein first reference bitcells and second reference bitcells of a same column store opposite data levels, and wherein first reference bitcells along the first reference bitcell row store alternating data levels and second reference bitcells along the second reference bitcell row store alternating data levels;
a first row of switching elements, configured to controllably connect respective first read bitlines of at least two adjacent columns together; and
a second row of switching elements, configured to controllably connect respective second read bitlines of at least two adjacent columns together.

According to some embodiments of the present disclosure, the memory array further includes a respective sense amplifier for each of the columns, having a first input connected to the first read bitline of the column and a second input connected to the second read bitline of the column, wherein an output of the sense amplifier is indicative of a level of a data bit stored in an addressed bitcell.

According to some embodiments of the present disclosure, respective reference data levels are repeatedly written to the first reference bitcells of the memory array and to the second reference bitcells of the memory array via respective write lines.

According to some embodiments of the present disclosure, the memory array further includes a preset element configured for presetting respective levels of the first read bitlines and the second read bitlines.

According to some embodiments of the present disclosure, for each of the columns the respective first read bitline and the respective second read bitline extend over the entire column, and wherein an unused portion of the respective first read bitline runs parallel to the second subset of the bitcells of the column and an unused portion of the second read bitline runs parallel to the first subset of the bitcells of the column.

According to some embodiments of the present disclosure, the first reference bitcells and the second reference bitcells are located on an axis of symmetry of the memory array.

According to some embodiments of the present disclosure, all of the bitcells in the memory array have a same structure.

According to some embodiments of the present disclosure, the first row of switching elements is controlled by a first control signal generated from an address of an accessed row and the second row of switching elements is controlled by a second control signal having an opposite level to the first control signal, such that the first row of switching elements and the second row of switching elements are closed at opposite times based on the address of the accessed row.

According to a second aspect of some embodiments of the present disclosure there is provided a method of accessing any embodiment of the memory array of the first aspect. The method includes:
for at least one row of the memory array addressed by an address signal:
   writing a data word to the addressed row;
   writing respective data levels to the first reference bitcells and to the second reference bitcells; and
   reading a data level from a bitcell of the array by:
      based on a value of a specified bit of the address signal, performing one of:
      connecting a read bitline of an addressed bitcell in a row associated with the first subset of bitcells to a first input of a sense amplifier and connecting a read bitline of a second reference bitcell in a same column as the addressed bitcell to a second input of the sense amplifier; and
      connecting a read bitline of an addressed bitcell in a row associated with the second subset of bitcells to the second input of a sense amplifier and connecting a read bitline of a first reference bitcell in a same column as the addressed bitcell to the first input of the sense amplifier.

According to some embodiments of the present disclosure, the method further includes determining a data level of the addressed bitcell from an output of the sense amplifier.

According to some embodiments of the present disclosure, the method further includes:
based on the value of the specified bit of the address signal, performing one of:
   coupling together read bitlines of the second reference bitcells of a plurality of columns; and
   coupling together read bitlines of the first reference bitcells of a plurality of columns.

According to some embodiments of the present disclosure, writing respective data levels to the first reference bitcells and to the second reference bitcells is performed during a hold state of operation of the array.

According to some embodiments of the present disclosure, the method further includes establishing a preset level on the read bitlines prior to a read operation.

Unless otherwise defined, all technical and/or scientific terms used within this document have meaning as commonly understood by one of ordinary skill in the art/s to which the present disclosure pertains. Methods and/or materials similar or equivalent to those described herein can be used in the practice and/or testing of embodiments of the present disclosure, and exemplary methods and/or materials are described below. Regarding exemplary embodiments described below, the materials, methods, and examples are illustrative and are not intended to be necessarily limiting.

Some embodiments of the present disclosure may be embodied as a circuit, memory, method or an embodiment combining software and hardware aspects.

For example, hardware for some embodiments of the present disclosure could be implemented as a chip or a circuit. As software, selected tasks according to some embodiments of the present disclosure could be implemented as a plurality of software instructions being executed by a computational device e.g., using any suitable operating system.

In some embodiments, one or more tasks according to some exemplary embodiments of method and/or system as described herein are performed by a data processor, such as a computing platform for executing a plurality of instructions. Optionally, the data processor includes a volatile memory for storing instructions and/or data and/or a non-volatile storage e.g., for storing instructions and/or data. Optionally, a network connection is provided as well. User interface/s e.g., display/s and/or user input device/s are optionally provided.

Some embodiments of the present disclosure may be described below with reference to flowchart illustrations and/or block diagrams. For example illustrating exemplary methods and/or apparatus (systems) and/or and computer program products according to embodiments of the present disclosure.

The flowchart and block diagrams in the Figures illustrate the architecture, functionality, and operation of possible implementations of devices systems and methods, according to various embodiments of the disclosed subject matter. For example, two blocks shown in succession may, in fact, be executed substantially concurrently, or the blocks may sometimes be executed in the reverse order, depending upon the functionality involved.

In order to understand the invention, embodiments will now be described, by way of non-limiting example only, with reference to the accompanying drawings. Features shown in the drawings are meant to be illustrative of only some embodiments of the present disclosure, unless otherwise indicated. In the drawings like reference numerals are used to indicate corresponding parts.

The various embodiments of the present disclosure are described below with reference to the drawings, which are to be considered in all aspects as illustrative only and not restrictive in any manner.

Elements illustrated in the drawings are not necessarily to scale, emphasis instead being placed upon clearly illustrating the principles of embodiments of the present disclosure. Moreover, two different objects in the same figure may be drawn to different scales.

### BRIEF DESCRIPTION OF THE FIGURES

FIG. 1A is a simplified array of bitcells which includes two rows (N and N+1) and sixteen bitcells per column.

FIG. 1B is a simplified block diagram of reference bitcells, according to an exemplary embodiment of the disclosure

FIG. 2 is a simplified flowchart of a method of accessing a row of a memory array, according to embodiments of the disclosure.

FIG. 3, which is a simplified diagram of a 16-kB 3T-1C GC-eDRAM macro in 65 nm technology, in accordance with exemplary embodiments of the disclosure.

FIG. 4A illustrates 3T-1C bitcell.

FIG. 4B illustrates the layout of a 2×2 subarray with added notation of the bitcell signals names and directions

FIG. 4C illustrates the operation of the PB signal is

FIG. 5A shows simulated waveforms of SN₀ and SN₁ levels when V_{BOOST} is selected to be 1.4V

FIG. 5B shows the DRT achieved for different values of V_{BOOST} over temperatures ranging from 0° C. to 85° C.

FIG. 5C shows the SN₀ level following a write operation for a range of V_{BOOST} values.

FIG. 6A shows three cells of the reference row.

FIG. 6B shows connecting every two adjacent RBLs with a PMOS device that is turned on by R̅W̅L̅r̅e̅f̅.

FIG. 7A plots the corresponding discharge rates of RBL₁, RBL₀, and RBL_{ref} are shown across 1000 Monte Carlo statistical simulations at 25° C. and V_{BOOST}=1.4 V.

FIG. 7B shows plotting the distributions of these states at the time of the assertion of the sense amplifier enable signal (DSA_en)

FIG. 8 shows the reference circuit uses a different bitcell.

FIG. 9A shows how RBL_{ref} tracks the RBL values throughout the evaluation phase.

FIG. 9B shows the distributions of RBL_{ref}, RBL₀, and RBL₁ for the time at which the DSA_en is asserted, after a simulated retention time of 100 μs.

FIG. 10 shows each subarray architecture is equipped with a pair of replica columns—one for the top half and one for the bottom half of the array—along with additional logic for controlling the self-timing mechanism.

FIG. 11 shows the timing waveforms of a typical read operation.

FIG. 12A shows the write peripheral block diagram for generating these boosted voltages.

FIG. 12B shows the waveform representation of the charge pump signals.

FIGS. 13A and 13B shows memory macro layout design and the test chip micrograph respectively.

FIG. 14 presents DRT measurements under different temperatures and V_{BOOST} values.

FIG. 15 shows the DRT of as a function of V_{BOOST} for several manufactured chips, demonstrating a similar trend of the V_{BOOST} effect.

FIG. 16 shows the retention map data of a subset of two subarrays, one designed with the shorted-RBL technique and the other with the SN_{ref} technique, measured at 25° C. with V_{BOOST} set to 1.35 V.

FIG. 17A shows the corresponding measurement results showing the achieved DRT at 99.9% yield for the SN_{ref} technique (shown in FIG. 6) compared to the shorted RBL technique (shown in FIG. 8).

FIG. 17B shows the results of the retention time dependency on V_{BOOST} for the two techniques.

### DETAILED DESCRIPTION OF EMBODIMENTS

The present disclosure, in some embodiments, thereof, relates to memory arrays and, more particularly, but not exclusively, to generating refresh rates for bitcells in a memory array.

The principles, uses and implementations of the teachings herein may be better understood with reference to the accompanying description and figures. Upon perusal of the description and figures present herein, one skilled in the art will be able to implement the teachings herein without undue effort or experimentation.

Before explaining at least one embodiment in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

Typically, a bitcell has two lines which are used for the write operation (WBL and WWL) and two lines which are used (RBL and RBW) which are used for the read operation. The signals applied to these lines during read and write operations (and possibly hold states) will be readily understood by the skilled person.

For clarity, some embodiments of the disclosure describe aspects of the memory array and method of accessing the memory array relating to the read operation only. The write operation may be performed in any technically suitable manner, with the addition of writing the appropriate data levels to the reference bitcells as described herein.

### I. Memory Array

According to some embodiments of the disclosure, a memory array includes multiple arranged in rows and columns. The rows store respective data words.

The memory array includes at least two columns. The bitcells in each column are divided into two segments. Each segment of bitcells (also denoted herein a subset of bitcells) has a respective read bit line. Two of the bitcells in each column are reference bitcells, one for storing a “1” data level and the other for storing a “0” data level.

For a given read operation, only one side of the array is read from. The side being read from is determined by a specified bit in the address (e.g., the most significant bit) of the address of the row being accessed. This division minimizes RC delay, making faster frequencies feasible.

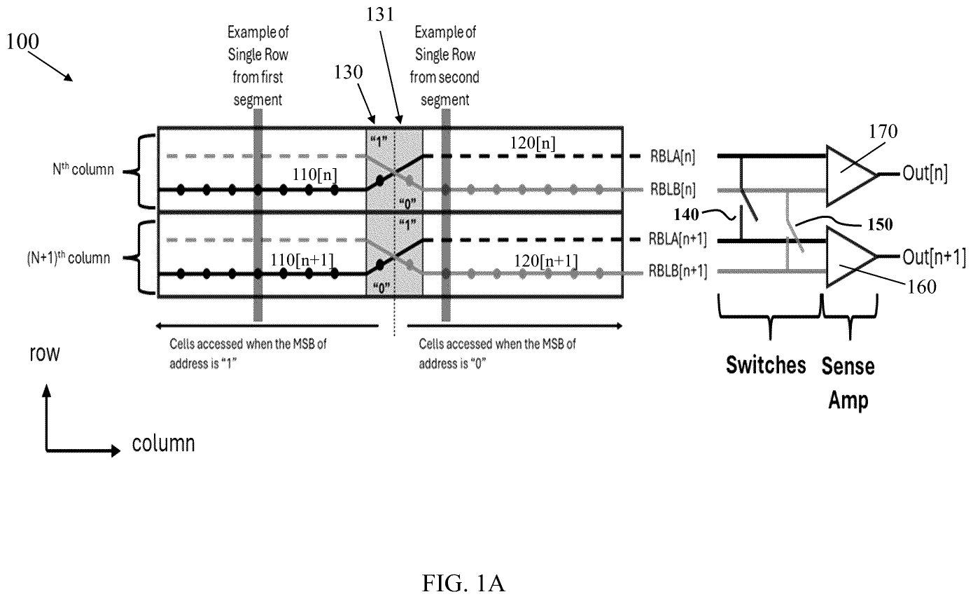

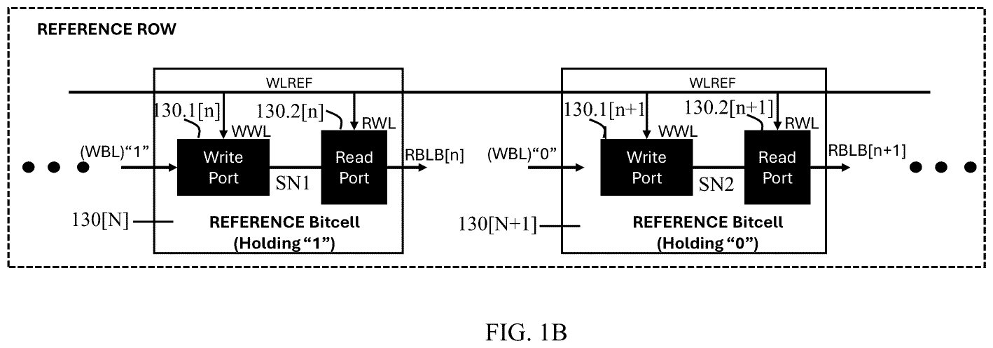

Reference is now made to FIG. 1A, which is a simplified exemplary embodiment of a memory array according to some embodiments of the disclosure. FIG. 1A is a non-limiting example which illustrates a simplified exemplary column layout, and is non-limiting as to the size of the memory array and to the layout of the bitcells within the array.

FIG. 1A is a simplified array of bitcells which includes two rows (N and N+1) and sixteen bitcells per column. The sixteen bits of column N include:
i) A first segment of data bitcells 110[n] which are accessed when the most significant bit (MSB) of the address is at data level “1”. The read bitline inputs of this segment of bitcells is RBLA[n].
ii) A second segment of data bitcells 120[n] which are accessed when the MSB of the address is at data level “0”. The read bitline inputs for this segment of bitcells is RBLB[n].
iii) Reference bitcell row 130 which includes two reference bitcell for each column. In column N, for example, the first reference bitcell stores a constant “1” data level and is connected to RBLA[n] and the second reference bitcell stores a constant “0” data level and is connected to RBLB[n].

Column N+1 has a similar structure, however the reference bitcells hold opposite data levels to the ones held by parallel reference bitcells in the preceding and following columns. In column N+1, for example, the first reference bitcell stores a constant “0” data level and is connected to RBLA[n+1] and the second reference bitcell stores a constant “1” data level and is connected to RBLB[n+1].

When the memory array includes more than two columns, this alternation of reference bitcell levels continues along the reference rows.

Each of the bitcells in the memory array is connected to a respective RWL (not shown here for clarity) which triggers a read operation of the bitcell.

In some embodiments of the disclosure, the data bitcells and/or reference bitcells

The memory array further includes two rows of switching elements. The first row of switching elements controllably connects the first read bitlines (e.g. RBLAs) of at least two adjacent columns together and the second row of switching elements, configured controllably connects the second read bitlines (e.g. RBLBs) of at least two adjacent columns together. In the two-column example of FIG. 1, each row of switching elements contains a single switching element, namely switches 140 and 150.

A used herein, according to some embodiments of the disclosure, the term “controllably connects” should be expansively construed to a switching element which connects and disconnects two or more lines (e.g. RBLAs or RBLBs) based on the level of a respective control signal applied to the switching element.

According to some embodiments of the disclosure, the first row of switching elements is controlled by a first control signal generated from the address of the accessed row (e.g. the level of the MSB) and the second row of switching elements is controlled by a second control signal having an opposite level to the first control signal. Thus the first and second rows of switching elements are closed at opposite times based on the address of the accessed row.

According to some embodiments of the disclosure, the memory array further includes and/or is connected to processing circuitry which process signals into and/or out of the memory array. In one non-limiting example, the processing circuitry provides respective control signals to the switching elements.

Typically, the memory array bitcells are connected to peripheral circuitry which provides analog and/or digital signals which control the operation of the memory array. An exemplary embodiment of a memory macro containing a memory array and peripheral circuitry is described in the exemplary embodiment presented below.

According to some embodiments of the disclosure, the memory array further includes a respective sense amplifier for each of the columns. Each sense amplifier has a first input connected to the column's first read bitline (e.g., RBLA) and a second input connected to the second read bitline of the column (e.g., RBLB). The sense amplifier output signal indicates the level of the data bit stored in the addressed bitcell. The exemplary embodiment of FIG. 1A includes two sense amplifiers 160 and 170.

According to some embodiments of the disclosure, respective reference data levels are repeatedly written to the memory array reference bitcells via respective write lines. The data level written to each reference bitcell remains constant during memory array operation and is of an opposite level to the second reference bitcell in its column and to adjacent reference bitcells in its row.

According to some embodiments of the disclosure, the memory array further includes a preset element, which is circuitry that presets (i.e. pre-charges or pre-discharges) respective levels of the read bitlines.

According to some embodiments of the disclosure, for each of the columns the two read bitlines (RBLA and RBLB) extend over the entire column. Each RBL has an unused portion (denoted herein a dummy RBL line) that runs parallel to the bitcell segment on the opposite side of the column. The dummy RBL lines are inserted into the layout to match the parasitic capacitance of the used portions of the RBLA and RBLB lines. In FIG. 1, the dummy RBLs are indicated by dashed lines.

According to some embodiments of the disclosure, the reference bitcells are located on an axis of symmetry of the memory array, in the center of the column. Placing the reference cells on the symmetry axis may improve yield during timed operations relative to yield when the reference bitcells are placed in a row that is not in the center of the column.

According to some embodiments of the disclosure, all of the bitcells in the memory array have the same structure (for example three-transistor, one-capacitor bitcells as presented in the example below).

Reference is now made to FIG. 1B, which is a simplified block diagram of reference bitcells, according to an exemplary embodiment of the disclosure. FIG. 1B shows the connections to reference bitcells in columns N and N+1 of row 130 in more detail.

In column N, reference bitcell 130[N] includes a respective write port 130.1[n] and a respective read port 130.2[n]. Write port 130.1[n] is connected to the WBL which writes a “1” data level into it when a write operation is triggered by the WWL, typically repeatedly to overcome leakage from the reference bitcell itself. During a read operation, the stored data is read from Read port 130.2[n] at RBLB[n].

The reference bitcell of column N+1 has a similar structure. Write port 130.1[n+1] is connected to the WBL which writes a “0” data level into it when a write operation is triggered by the WWL, typically repeatedly to overcome leakage from the reference bitcell itself. During a read operation, the stored data is read from Read port 130.2[n+1] at RBLB[n+1].

### II. Accessing the Memory Array

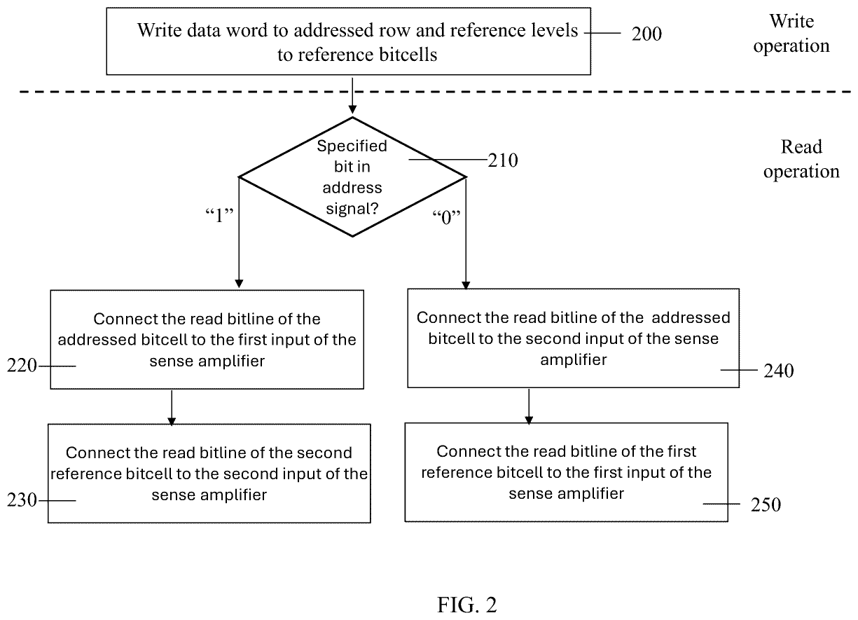

Some embodiments of accessing a memory array in accordance with the disclosure are now presented. The memory array includes a reference row which contains two reference bitcells per column as described herein. For clarity, FIG. 2 describes writing to and reading from the same row of the memory array.

Reference is now made to FIG. 2, which is a simplified flowchart of a method of accessing a row of a memory array, according to embodiments of the disclosure.

In 200 a data word is written to the data bitcells of the accessed row of the memory array. The write operation is performed by any method that is suitable for the bitcell structure. Reference data levels are written to the reference bitcells in the reference row as described above, where for each column one reference bitcell holds a “0” and the other reference bitcell holds a “1”.

In 210-240 a read operation is performed on a data bitcell.

In 210 the value of a specified bit in the address (the MSB for the purposes of the instant exemplary embodiment) is determined.

If the MSB of the address input is “1”, in 220 the RBLA of the addressed bitcell in one segment is connected to the first input of a sense amplifier. In 230 the RBLB of the reference bitcell of the other segment in the same column is connected to the second input of the sense amplifier. 220 and 230 are performed simultaneously.

If the MSB of the address input is “0”, in 240 the RBLB of the addressed bitcell in the row is connected to the second input of the sense amplifier. In 250 the RBLA of the reference bitcell of the other segment in the same column is connected to the first input of the sense amplifier. 240 and 250 are performed simultaneously. According to some embodiments of the disclosure, the method further includes determining the data level of the addressed bitcell from the sense amplifier output.

According to some embodiments of the disclosure, the method further includes coupling together read bitlines in multiple columns based on the MSB. When the MSB is at “1”, the RBLBs are coupled together. When the MSB is at “0”, the RBLAs are coupled together.

According to some embodiments of the disclosure, the data levels are written to the reference bitcells during a memory array hold state.

According to some embodiments of the disclosure, the method further includes establishing a preset level on the read bitlines prior to the read operation.

In an exemplary embodiment of the disclosure, a read operation is performed as follows:
i. The read bit lines (RBLs) in the memory array are pre-charged or pre-discharged according to the read mechanism.
ii. A mimic write operation is performed on the reference cells to calculate the write coupling effect on the stored bit cell.
iii. According to the accessed part of the array (MSB “0” or “1”), the other half's RBL lines (RBLAs or RBLBs) are shorted together. This may minimize mismatch variation effects and obtain an average reference value for a reliable read operation.
iv. The read word line signal is applied to both the bitcells and the reference cells. If the read operation is performed on the left side of the array (MSB=1), the right-side reference is enabled; if the operation is on the right side (MSB=0), the left-side reference array is enabled.
v. The reference cells discharge or charge one side of the array (RBLA or RBLB), while the target bitcells charge or discharge the other side of the array, and their stored value is translated into the RBL lines.
vi. The sense amplifiers then determine the digital output value according to the analog voltage/current levels on the RBL lines.

In some embodiments of the disclosure, the speed of read operation is enhanced by combining the write mimic operation and enabling the refence row. To achieve this, the write operation for the refence cells may be enabled at the hold state (it is the state, which there is a no operation in the array) and enabling the read path turns off the write operation so that its coupling effect is included while reading.

### III. Exemplary Memory Array Macro and Simulation Results

Non-limiting examples of the memory array and memory macro in accordance with embodiments of the disclosure are presented. The memory array includes an array of three-transistor, one-capacitor (3T-1C) bitcells for data storage. For the purposes of this example, the array(s) of data bitcells are referred to as the “bitcell array” and the bitcell array with additional circuitry (such as the reference bitcells and other peripheral circuitry) are denoted the “memory macro” or “macro”.

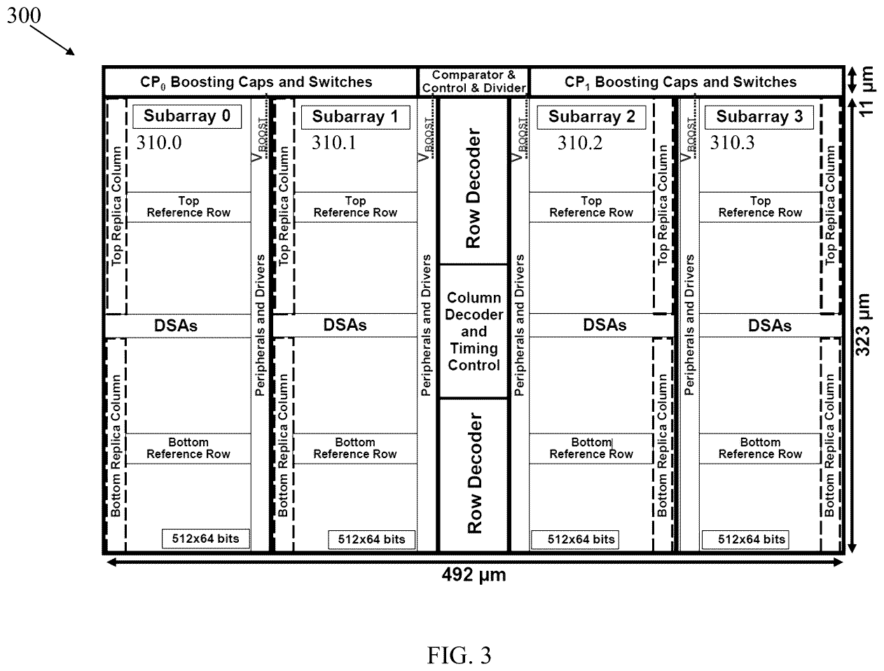

Reference is now made to FIG. 3, which is a simplified diagram of a 16-kB 3T-1C GC-eDRAM macro in 65 nm technology, in accordance with exemplary embodiments of the disclosure. This example includes a unique internal reference voltage generation mechanism and an on-chip DC-DC converter for internal boosted supply generation. Memory macro 300 features variation-tolerant sensing technique that includes an internal dynamic reference voltage used for the DSA. The memory is organized as two segments for exploiting the peripherals of one half of the array to generate the reference for the other half. Each half is separately controlled to enable the reference technique, while leaving the memory density unaffected. The reference voltage is created in-memory, sparing an additional analog voltage source, and placed within the bitcell array, resulting in similar effects of process variation and coupling capacitance on both the array bitcell and the reference circuit.

Furthermore, the implemented DC-DC converter is used as a local write voltage booster during write operation to improve the storage node separation between stored ‘0’ and ‘1’ levels and during the idle state to reduce subthreshold leakage. This results in a significant improvement of charge loss in the storage node resulting in extended retention time. The DC-DC converter is placed at the top of the memory macro (FIG. 3) and optimized for minimum area (11 μm×492 μm). The main charge-pump logic is laid out according to the decoder placement, and the pumping circuits are placed at the top of the sub arrays. The layout of the boosting capacitors is pitch-fitted to the width of the 64 bit cells to achieve design regularity. The charge pump shares the input clock with the array and it can generate a boosted supply with a frequency range of 1 MHz to 250 MHz.

Significant area reduction of the DC-DC converter was achieved by high-frequency operation and with low-leakage drivers.

This exemplary embodiment of memory macro according to aspects of the disclosure demonstrate the following advantages:
1) A low area-overhead macro-architecture design realizes an internal reference voltage for the read-out sensing scheme. The unique organization of the memory array partitioning allows to implement and control a reference RBL for the corresponding RBL in the other memory sector.
2) Two examples of reference row circuits for integration within the array to increase DRT with enhanced variation tolerance and low area overhead are presented.
3) An area and power efficient on-chip DC-DC converter is implemented for internally generating the boosted voltage.
4) Increase DRT relative to similarly arranged arrays of data bitcells by boosting the capacitor device within the 3T-1C bitcell.
5) Provide a significant improvement in DRT compared to other memory macros in the same technology, while internally generating all required reference voltages.

Section III.1 presents the architecture of the memory macro and its main circuit features; Section III.2 presents the fabricated test chip and measurement results, and Section IV concludes the paper.

### III.1. Macro Architecture Design

FIG. 3 shows a schematic view of an exemplary GC-eDRAM macro according to embodiments of the disclosure. The 16-kB macro is constructed from four identical data bitcell subarrays 310.0-310.3 of 512×64-bits, where each subarray is divided into two vertical sections. A set of 64 pitch-fitted DSAs are placed between the top and bottom 256 rows of each subarray. The middle gap between the two left and two right subarrays is used to implement the global decoders, drivers and control logic. Further peripherals and drivers are located adjacent to each subarray. This organization optimizes the layout for parasitic equivalence between sections, as required for the replica mechanisms presented herein, while minimizing the area and power overheads.

The memory architecture includes two internal replica mechanisms. Both of these mechanisms utilize a single row of reference cells that is integrated into the middle of each half (top and bottom) of the subarray and an additional column, as shown in FIG. 3.
1) An internal reference voltage generator for differential sensing. During read operations, the selected row conditionally discharges the RBLs of each column in the section (top or bottom) in which it resides. At the same time, the reference row is activated in the other section, and its corresponding RBLs are used to generate the reference voltage for the DSAs.
2) A self-timing mechanism for controlling the read operation. An additional column, referred to as the replica column, is added to the array to control the timing of the precharge, evaluation, and sensing phases of a read operation.

The following subsections elaborate on the primary components and mechanisms provided in memory macro 300, which enable extending the DRT and mitigating susceptibility to process variations and changing operating conditions.

### A. 3T-IC Bitcell

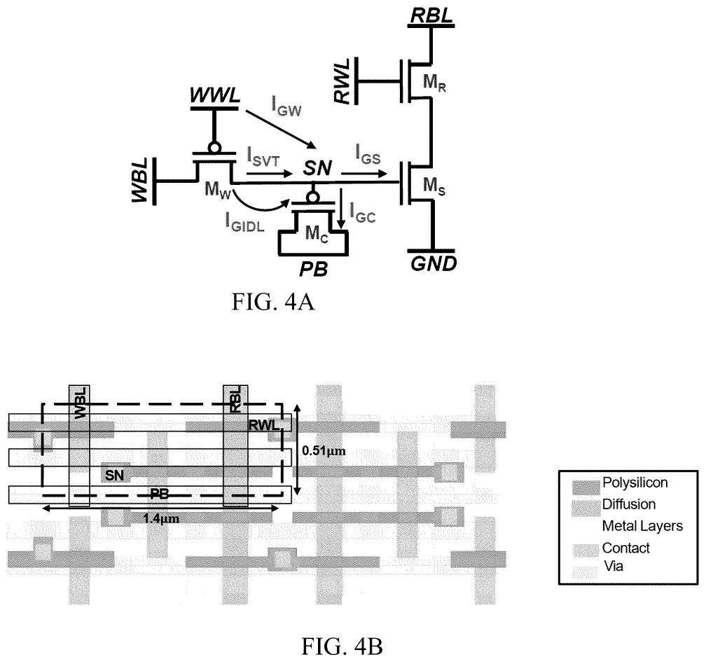

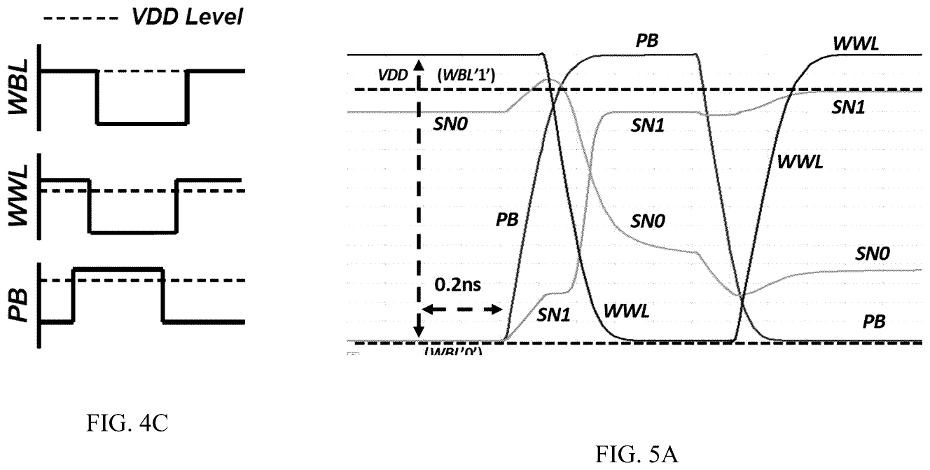

Dynamic memories are attractive due to their reduced transistor count as compared to their static (SRAM) counterparts, but have limited data retention time, since the stored charge leaks away over time. In addition, charge injection and clock-feedthrough (CI/CF) during write word line (WWL) dis-assertion of a write operation degrade the storage node (SN) level, causing a decrease in DRT due to a lower initial SN voltage. To alleviate this issue, a three-transistor, one-capacitor (3T-1C) bitcell was used in memory macro 300. The 3T-1C bitcell is illustrated in FIG. 4A. The source and drain nodes of the MOS capacitor (M_{C}) are connected to an additional signal, PB, which is shared by all cells in a row. The addition of the PB signal assists in mitigating the CI/CF phenomenon by boosting the SN value to the opposite direction through capacitive coupling.

FIG. 4B illustrates the layout of a 2×2 subarray with added notation of the bitcell signals names and directions. The horizontal signals, WWL, read word line (RWL), and PB are drawn in metal layer 3, while the vertical signals, RBL and write bit line (WBL) are drawn in metal layer 2. The PB signal is shared between every two bitcells, by horizontally flipping every other bitcell, such that the PB wires are overlapped.

The operation of the PB signal is illustrated in the waveforms of FIG. 4C. The PB signal is raised when WWL is asserted, such that it is high while the WBL voltage is passed through M_{W} to the SN. When writing a ‘1’, the full V_{DD} level will be passed to the SN (referred to as SN₁); however, when writing a ‘0’, a threshold voltage (V_{T}) drop will occur, resulting in a degraded SN level (referred to as SN₀). This phenomenon is exacerbated when a boosted voltage (V_{BOOST}>V_{DD}) is applied following a write operation in order to reduce the dominant subthreshold leakage through the write transistor. When WWL is dis-asserted, the voltage swing from GND (or a negative voltage to overcome the aforementioned V_{T}-drop) to the off-state voltage (V_{BOOST}) results in a significant increase in the SN₀ level, further raising the already-degraded ‘0’ level. In memory macro 300 the PB signal is boosted together with WWL. The coupling of the MOS capacitor to the SN node combats the CI/CF effects and results in a better SN₀ level than in previous publications. The SN₁ level is less critical, as in addition to not suffering from V_{T}-drop, its deterioration due to subthreshold leakage is not as severe.

FIG. 4A includes annotations for the primary leakage currents that affect the storage node. SN₁ is influenced by the gate leakages of the M_{S} and M_{C} transistors, represented by I_{GS} and I_{GC} respectively. On the other hand, the SN₀ level is affected by the gate current (I_{GW}), sub-threshold leakage (I_{SVT}), and gate induced drain leakage current (I_{GIDL}) of the M_{W} transistor. The largest leakage component is the sub-threshold leakage, especially at high temperatures, and it is suppressed by the boosted WWL voltage. Other components are balanced to increase the DRT.

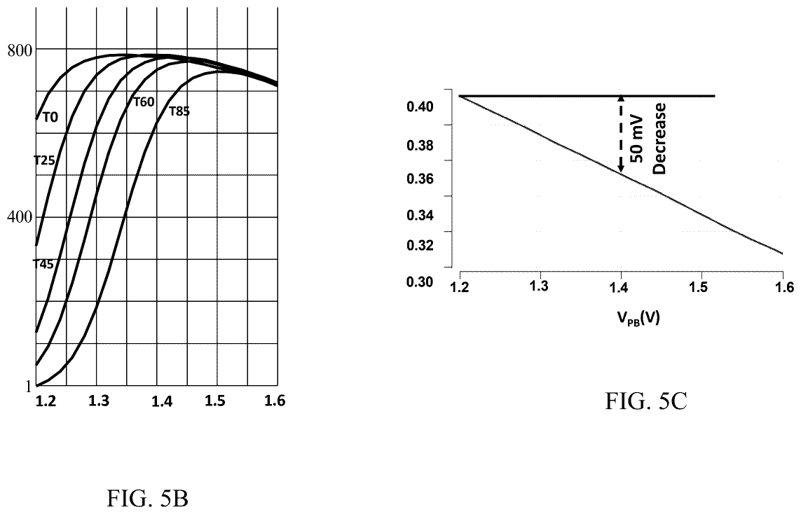

FIG. 5A shows simulated waveforms of SN₀ and SN₁ levels when V_{BOOST} is selected to be 1.4V. The drop in SN voltage due to PB is shown to be stronger than the rise due to CI/CF, such that the final value of SN₀ is even lower than the initial value transferred from WBL. The final SN₁ level remains close to V_{DD}. FIG. 5B shows the DRT achieved for different values of V_{BOOST} over temperatures ranging from 0° C. to 85° C. The peak of the curve shifts with temperature increase due to drain-induced barrier lowering (DIBL). FIG. 5C shows the SN₀ level following a write operation for a range of V_{BOOST} values. A 50 mV reduction was achieved for V_{BOOST}=1.4V, which provides a good trade-off for enhanced DRT, while remaining inside the recommended operating envelope of the technology.

As for the read operation, the RBL is pre-charged to V_{DD} using a PMOS transistor, followed by an assertion of the RWL signal for initiating the evaluation phase. RBL is then conditionally discharged according to the level of SN stored in the bitcell and sensed using a DSA for evaluating the data output.

### B. Reference Voltage Generation

As opposed to 6T-SRAM, which features a pair of bitlines that can be compared for evaluating the content of the storage cell, GC-eDRAM utilizes a single-ended readout mechanism. The sensing of this type of circuit can be done by simply using an inverter; however, differential sensing is beneficial for both performance and for improving the read margins under PVT variations. Unfortunately, the rate of RBL discharge in typical GC-eDRAM designs suffers from high levels of variation, not only due to PVT conditions, but also due to the dependence on the stored data voltage level on the SN that is highly sensitive to coupling effects.

To address this challenge, the GC-eDRAM macro 300 utilizes an internally generated reference RBL. By integrating the reference generation mechanism within the memory itself, both PVT variations and coupling capacitance effects can be tracked, such that the generated dynamic voltage can follow the same variations as the RBL voltage to which it is compared. The replica mechanism for self-timing, described below further improves the tracking, as the optimal time for sensing the RBL is also variation dependent.

The reference voltage generation is achieved by integrating a reference row (64 reference cells) into each half (top and bottom) of every subarray 310.0-310.3. Based on the most-significant bit (MSB) of the read address provided to the subarray, either the top or bottom reference row (RBL_{ref}) is activated. The reference row discharges the RBLs of the non-selected half of the subarray (e.g., the bottom half, if the addressed row is in the top half of the subarray) at a rate that is configured to be in-between the RBL voltage of reading a ‘0’ (denoted RBL₀) and reading a ‘1’ (denoted RBL₁). The voltages of the selected RBL and the non-selected RBL (RBL_{ref}) are compared by the DSAs to provide the read out data.

Two exemplary embodiments of reference rows are now presented. Both circuits feature the same read port as that of the primary 3T-1C storage cell (FIG. 4A) to match process variations and coupling capacitance effects and to case pitch-fitting the read peripherals. The reference generation is done within the read cycle, and therefore, the timing is not affected. Each of the two reference row designs described in the following, were integrated within two of the four subarrays to enable a fair comparison based on measurements.

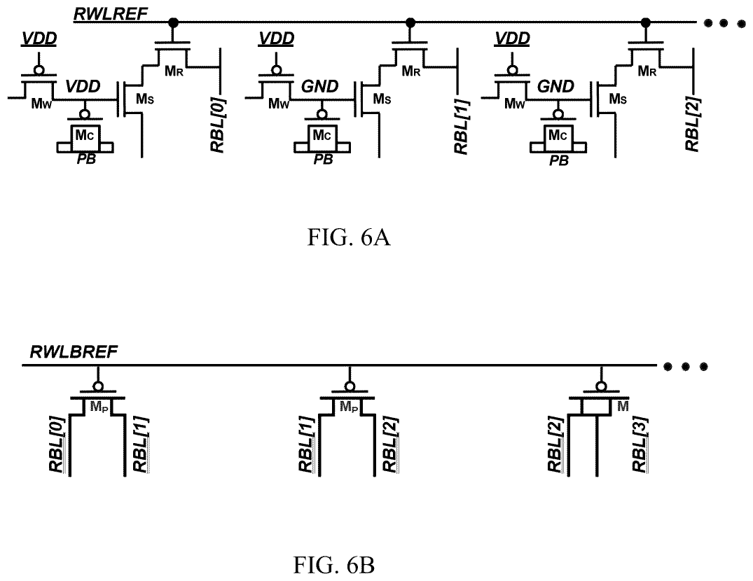

1) Reference Row with Shorted-RBL: In a first example, the reference circuit is based on the same 3T-IC structure as the one used for the bitcells; the only difference is that the SNs of the reference cells are hard-wired to either V_{DD} or GND and that the write port (WWL) is hard-wired to V_{DD}. Three cells of the reference row are shown in FIG. 6A, also pointing out that the read port is controlled by RWLref. The RBLs in the non-selected half of the array are shorted together, thus creating a median discharge voltage, RBL_{ref}, that lies in between what is expected from an RBL associated with SN₀ and SN₁. This is achieved by connecting every two adjacent RBLs with a PMOS device that is turned on by R̅W̅L̅r̅e̅f̅ as shown in FIG. 6B.

The ratio of the number of hard-wired V_{DD} and GND reference cells that generate RBL_{ref} that lies perfectly in between RBL₀ and RBL₁ is found through simulation. While in the example of FIG. 6A, one reference cell is hard-wired to V_{DD} and two to GND, Monte Carlo (M_{C}) and post-layout simulations, yield an optimal ratio of 3:1 GND and V_{DD} reference SN voltage levels. Simulations were carried out assuming a worst-case retention time of 100 μs and tested under global corner variations to ensure the reference signal tolerance to variation and ideal tracking for different process corners, as allowed by the unique design and integration. Different simulated ratios, including either equal ratio of V_{DD} and GND, or more V_{DD} than GND nodes, result in unsuccessful ‘1’ read-outs due to faster discharge of RBL_{ref} that overlaps with the wide distribution RBL₁. On the other hand, reading a ‘0’ is compromised when adjusting the ratio to a higher number of GND nodes due to a smaller discharge rate of RBL_{ref}.

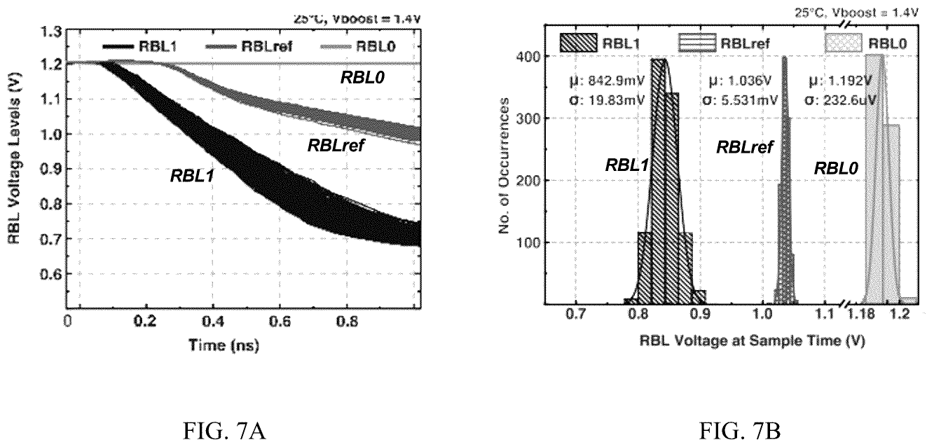

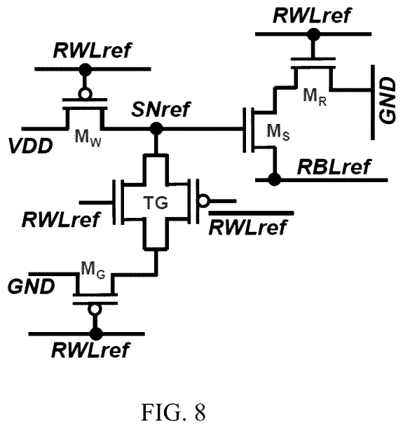

FIG. 7A plots the corresponding discharge rates of RBL₁, RBL₀, and RBL_{ref} are shown across 1000 Monte Carlo statistical simulations at 25° C. and V_{BOOST}=1.4 V. The transient plots clearly show that RBL_{ref} is well-tuned to be in between the two readout states. The quality of this placement is further demonstrated by plotting the distributions of these states at the time of the assertion of the sense amplifier enable signal (DSA_en) in FIG. 7B.
2) Reference Row with SN_{ref} Generation: In a second example, the reference circuit uses a different bitcell, shown in FIG. 8.

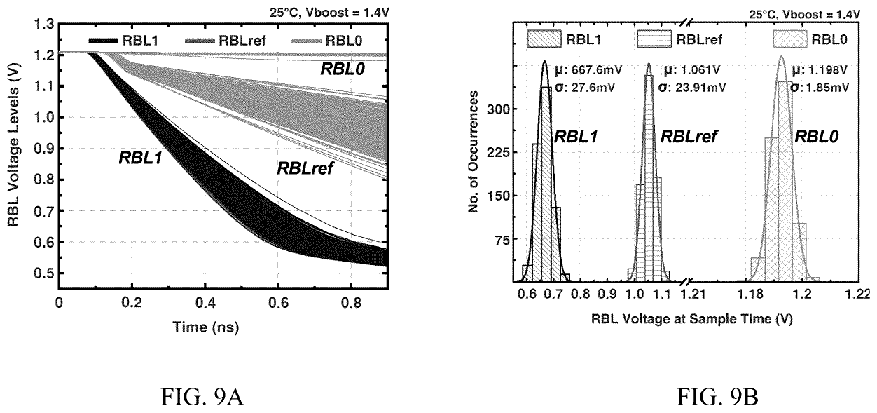

This circuit forms a voltage divider through two write ports to provide an intermediate voltage on SN(SN_{ref}) that creates an RBL discharge rate that is in between RBL₀ and RBL₁ (RBL_{ref}). This voltage divider is created by hard-wiring the WBL of the original 3T structure to V_{DD} and replacing the MOS capacitor (M_{C}) with an additional write transistor (M_{G}) that is connected between GND and a transmission gate (TG). Both of the write transistors are activated with RWLref, such that upon accessing the other half of the subarray, the voltage at SN is set as a contention between M_{W} and M_{G}. FIG. 9A shows how RBL_{ref} tracks the RBL values throughout the evaluation phase and FIG. 9B shows the distributions of RBL_{ref}, RBL₀, and RBL₁ for the time at which the DSA_en is asserted, after a simulated retention time of 100 μs. The SN_{ref} level is determined following extensive Monte Carlo, PVT, and post-layout simulations, verifying that SN_{ref} corresponds to the targeted reference signal. Similar to the simulations of the first technique (FIG. 7B), the generated RBL_{ref} voltage clearly separates the two possible readout states of the data.

While both examples provide a well-defined reference voltage for robust readout, simulation results show a slight advantage for the first exemplary embodiment over the second. This may be explained by greater resilience to mismatch of the first reference topology where RBL_{ref} is generated through many parallel reference cells (connected by shortening the bit lines), which statically hold voltages of V_{DD} and GND in the SN, thereby contributing to the generated voltage robustness. In the second topology, each reference bit line is only controlled by two devices which are prone to variations, leading to a wider distribution of RBL. In terms of area overhead, the SN_{ref} generation row presents an overhead of 0.77%, while the Shorted-RBL technique has a slightly larger area overhead of 1.9% due to the addition of the PMOS row.

C. Self-Timing with Replica Column

The timing of memory control signals is a complex task that is important to ensure robust operation under process variations and changing operating conditions. For dynamic memories that feature retention time dependent RBL discharge rates, this task becomes even more challenging. The macro 300 adds a replica column to track the process variations and PVT conditions to adjust the timing of read operation to achieve robust operation with extended DRT.

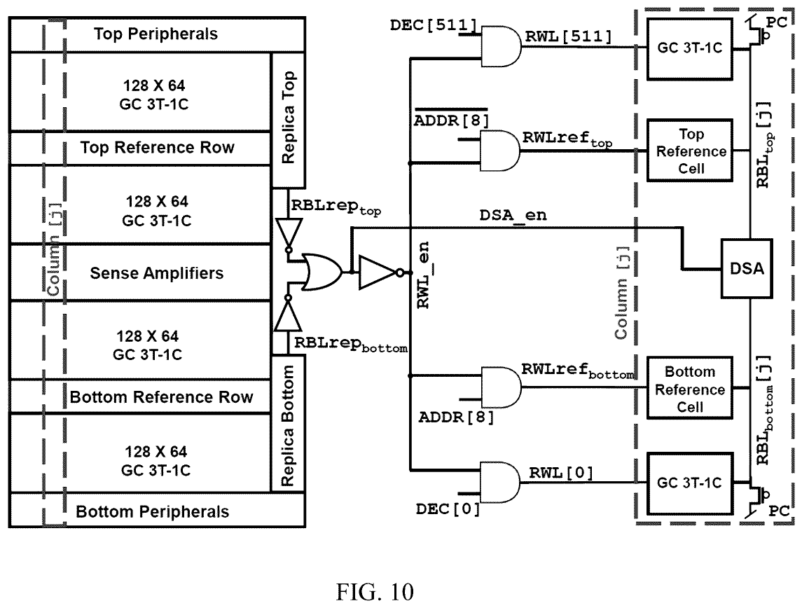

Each subarray architecture is equipped with a pair of replica columns—one for the top half and one for the bottom half of the array—along with additional logic for controlling the self-timing mechanism, as shown in FIG. 10. The replica column is made up of the same 3T-1C cells of FIG. 4A; however, the gates of the M_{R} transistors are grounded for all but the cell in the reference row, which is connected to RWLref. Furthermore, the storage node of this cell is hard-wired to V_{DD}, such that when RWLref is asserted, the replica cell discharges the RBL of the replica column (RBLrep).

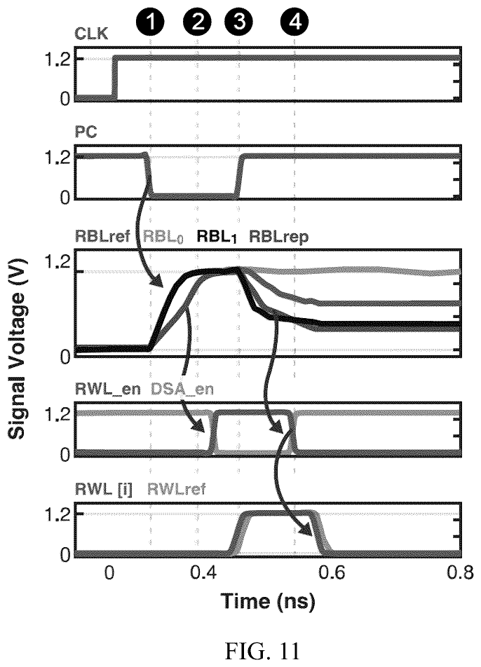

The timing waveforms of a typical read operation are shown in FIG. 11, as extracted from circuit-level simulations in a subarray, including peripherals of the read path. A read operation is initiated when the precharge signal (PC) goes down (time 1), enabling the PMOS devices that charge the RBLcapacitances across the entire memory, including the RBLrep wires. As soon as both top and bottom RBLrep signals are precharged (time 2), the RWL_en signal rises. This signal is ANDed with the row decoder output (DEC[i] for rows 0 to 511) to assert the RWL signal for the selected row (time 3). In addition, the RWL_en signal is ANDed with the MSB of the address space of the subarray (denoted ADDR[8] in FIG. 10) to assert the RWLref signal for the bottom half of the subarray, and with the inverted MSB for the RWLref of the top half of the subarray.

When the selected RWL becomes high, the RBL lines start discharging, depending on the value of the SN 3. The waveforms of FIG. 11 show the discharge rate of the RBL of a column storing a ‘0’ in the selected row (RBL₀), a ‘1’ in the selected row (RBL₁), and one of the RBLs of the replica section (RBL_{ref}) that is used as a reference in the differential sensing scheme.

At the same time, RBLrep discharges at a rate that is higher than RBL₀ but lower than RBL₁, as can be seen in FIG. 11. Once RBLrep drops below the threshold of the inverter that it is connected to, the DSA_en signal rises, initiating the operation of the DSA (time 4). In addition, the RWL_en signal goes down, stopping the discharge of the RBLs, ensuring that the sensing occurs without further RBL discharge, and thereby saving power.

The self-timing of the replica column (including the subsequent control gates) can be configured by design time-based PVT and MC simulations. By simply disconnecting the diffusion of some of the M_{R} devices in the replica column from RBLrep, its capacitance is reduced, resulting in a discharge rate slightly slower than RBL₁. The number of disconnected replica column cells was simulated and found to be 178 out of the 256 rows.

### D. Write Peripherals

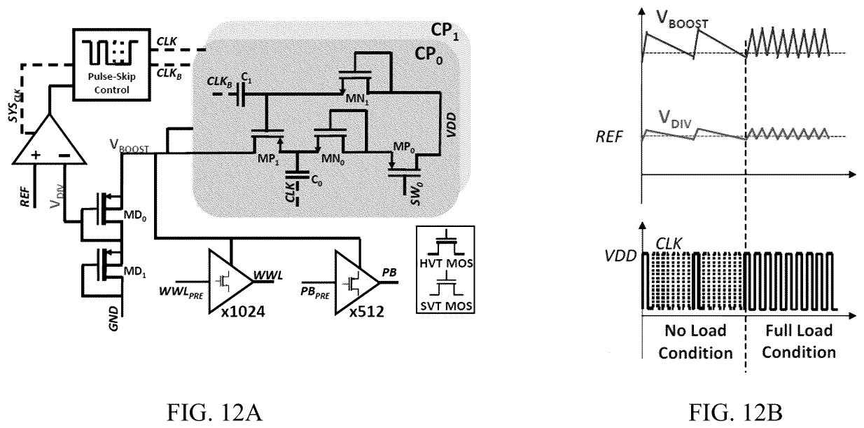

The previous subsections introduced the array architecture, stating that two signals, WWL and PB, need to be driven to a boosted voltage (V_{BOOST}) during their respective operation. The write peripheral block diagram for generating these boosted voltages is shown in FIG. 12A. This block consists of two identical boosting cells (CP₀ and CP₁), which constitute a charge pump. To control the V_{BOOST} level, the output is divided by two high-V_{T} (HVT) diode-connected PMOS transistors (MD₀ and MD₁) and compared with a reference voltage (REF) using a dynamic comparator. The clock signals (CLK and CLK_{B}) are controlled by the pulse-skip method and they are toggled according to the comparator output. The charge pump uses the system clock and can operate between 1 MHz and 250 MHz. It is optimized for minimum area, and occupies only 3% of the 16-kB macro. To achieve this small area, the output capacitance is realized with the parasitic capacitance of the WWL lines. Since only one write operation can be made in a single clock cycle, 1023 WWL lines are always shorted to the boosted voltage and act as output load.

FIG. 12B shows the waveform representation of the charge pump signals. Two different loading conditions are represented: the no-load condition, referring to the hold state, and the full-load condition, representing the refresh operation. According to the double-sided latch-based comparator output (comparison between REF and V_{DIV}), the clock (CLK) signal is passed through the charge pumps (solid CLK lines) and increases the V_{BOOST} voltage level. The comparison occurs at every clock cycle to achieve smaller ripple voltages. The V_{DIV} voltage is generated from V_{BOOST} by dividing the voltage in half, using the MD₀ and MD₁ transistors. The threshold voltages and sizes of these diode-connected transistors are selected based on the optimal balance between power consumption (leakage from V_{BOOST} to GND over diodes) and maximum operating frequency. The main parameter effecting the DRT when using the charge-pump circuit instead of an external supply voltage is the ripple voltage. By comparing every cycle and using a moderate output capacitance, the charge pump circuit can instantly react to a write operation and generate a nearly constant V_{BOOST} voltage with ripples that are smaller than 20 mV. This 20 mV ripple for a V_{BOOST} of 1.4 V at 85° C. causes less that a 2% degradation of DRT (Normalized DRT is 628 and 640 for 1.4 V and 1.42 V, respectively, as can be seen in FIG. 3(b))

The charge pump is constructed from two identical pumps (CP₀ and CP₁). Their structure is based on the bootstrap topology. Since the required gain is less than 2×, voltage drops on the diodes (MN₀ and MN₁) are not an issue for the exemplary system. Moreover, the diodes limit the maximum voltage rating on the WWL and PB lines to avoid lifetime reliability issues. The MP₀ transistor enables the operation of the chosen charge pump. The power output of a single charge pump is sufficient up to 90° C. at an operating frequency of 250 MHz. The second pump can be enabled when high power is required (e.g., under high temperatures, high supply voltage levels, and aging).

To prevent write failures due to timing constraints, the enable signal of WWL is derived from a delayed version of the PB enable signal that is connected to the selected word-line with matching delays. To ensure matching, the first stage of the drivers of the PB and WWL signals are designed with a matching layout organization. In addition, the delay between the PB and WWL enable signals is designed to be long enough to compensate for local variations on the drivers.

To decrease the power requirement of the V_{BOOST} node, the drivers utilize HVT devices. The NMOS devices of the WWL drivers and PMOS devices of the PB drivers are selected as HVT. Since the default state of the outputs of the PB and WWL drivers are GND and V_{BOOST}, respectively, the resistance between GND and V_{BOOST} significantly increases by using HVT devices, such that the V_{BOOST} current is 22% lower than when using nominal V_{T} devices. That said, the design of the write peripheral block prioritizes area over power. It consumes a very small area footprint and follows the pitch of the bit cells.

By using boosted PB drivers and feeding them from the charge pump, the required V_{BOOST} power is increased by 50% resulting in a 10-15% extension of the DRT. This results in a 4% increase in total power consumption, since the majority of the power is consumed by charging and discharging the bit lines during write operations.

### III.2. Test Chip Implementation and Measurements

A test chip containing the 3T-1C 16-kB GC-eDRAM macro was fabricated in a 65 nm CMOS technology and integrated into a SoC with RISC-V core. An AXI interconnect system bus connects the GC-eDRAM block to the CPU for controlling the block, carrying out measurements, and for demonstration [27].

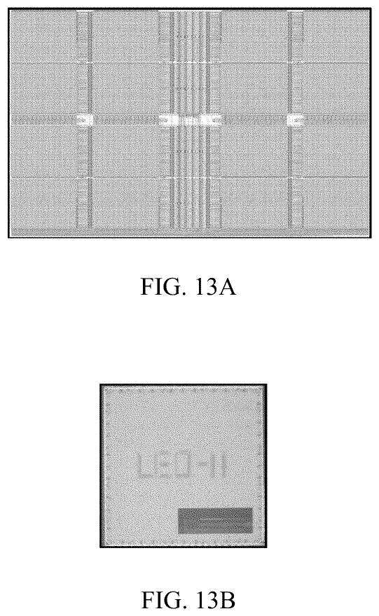

The memory was tested using a program for characterizing retention time across boosted voltage values under varying temperatures from 0° C. to 85° C. The retention time measurements were done by accessing the full memory array under worst-case conditions at a 100 MHz frequency. The memory macro layout design and the test chip micrograph are shown in FIGS. 13A-13B respectively. The main features are given in

### Table 1:

TABLE 1

| | | | |
|---|---|---|---|
| Process | 65 nm CMOS | Temperature | 0° C.-85° C. |
| Die Size | 3 mm × | Core Voltage | 1.2 V |
| | 3 mm | | |
| Memory | 128 kb | Boosted | 1.2 V-1.5 V |
| Capacity | | Voltage | |
| Memory | 312.4 μm × | Retention Time | 369 μs @ 250° C., |
| Size | 493.26 μm | @ 99.9% | 126 μs @ 85° C. |
| Bitcell | Mixed 3T-1C GC | Power | 40.3@ 25° C., |
| Type | | μW/MHz | 139.2 @ 85° C. |

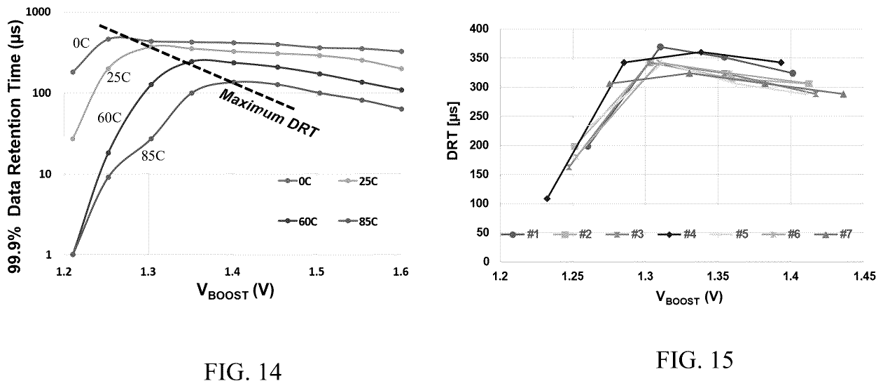

FIG. 14 presents DRT measurements under different temperatures and V_{BOOST} values. The measured retention times are for 99.9% yield. The DRT increases for lower temperatures due to reduced leakage currents. Boosting the WWL/PB voltage from 1.2 V to 1.4 V is shown to significantly increase the DRT across all measured temperatures. Further increase of V_{BOOST} beyond a certain (temperature dependent) level does not provide additional benefits; however, it also does not degrade the DRT. Therefore, the highest V_{BOOST} can be set for the entire temperature range without significant penalty.

FIG. 15 shows the DRT of as a function of V_{BOOST} for several manufactured chips, demonstrating a similar trend of the V_{BOOST} effect. The measured retention times are 369 μs and 133 μs for 99.9% and 99.99% yield respectively with a 1.31 V boosted voltage at room temperature, and 126 μs and 48 μs for 99.9% and 99.99% yield respectively with a 1.4 V boosted voltage at 85° C. The worst case required refresh power of the full macro is measured at 139 μW/Mb and the leakage power is 63.6 μW at 85° C. These worst case conditions were measured by setting the frequency, temperature and V_{BOOST} to 250 MHz, 85° C. and 1.4 V, respectively. WWL and PB lines are driven by V_{BOOST}, while the RWLs and RBLs are connected to the 1.2 V (V_{DD}) supply.

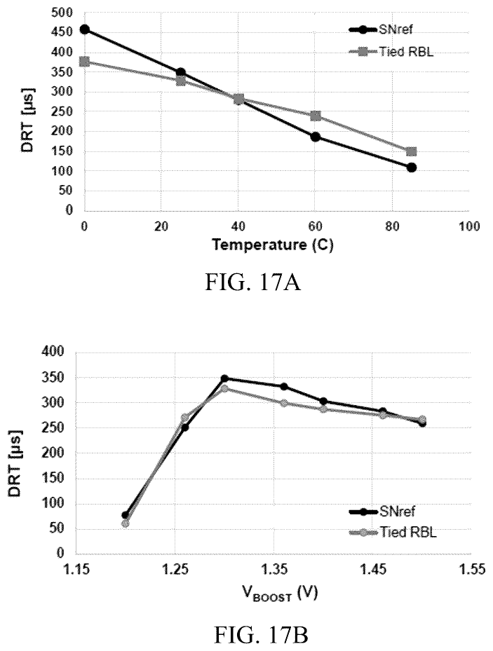

Additional measurements compare the operation of the two different exemplary reference voltage generation schemes, described in Section III.1.B above, by testing the respective subarrays with each implementation. The corresponding measurement results are shown in FIG. 17A, showing the achieved DRT at 99.9% yield for the SN_{ref} technique (shown in FIG. 6) compared to the shorted RBL technique (shown in FIG. 8). The results of the retention time dependency on V_{BOOST} for the two techniques are shown in FIG. 17B. The two techniques show similar results, with the SN_{ref} technique slightly superior at lower temperatures and the shorted RBL technique slightly better at higher temperatures. Power measurements were carried out on the two different subarrays, demonstrating similar results for both techniques, indicating that the power consumption resulting from the reference generation is insignificant.

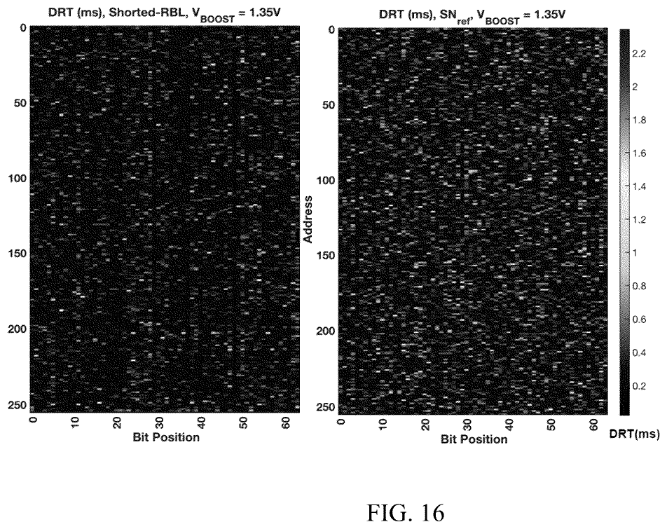

FIG. 16 shows the retention map data of a subset of two subarrays, one designed with the shorted-RBLtechnique and the other with the SN_{ref} technique, measured at 25° C. with V_{BOOST} set to 1.35 V. Moreover, the charge pump startup time was measured to be a few milliseconds, which has been taken into account in the DRT measurements. However, this should not pose a problem during actual operation, as the memory circuit is designed to remain powered on, with the generated boosted voltage staying constant after the initial startup period.

In summary, the exemplary memory macro according to the disclosure presents a 3T-1C GC-eDRAM macro architecture utilizing a novel concept for generating a tracking dynamic reference voltage for a single-ended sensing scheme. Two custom techniques for reference voltage generation were presented and compared. Supported by minor peripheral additions, the rows generating the reference voltage are integrated inside the memory array to cope with PVT variations and coupling capacitance effects, increasing the read margin for a faster, more accurate read. This results in improved DRT and eliminates the need for an externally supplied reference voltage. By dividing the memory array into two sections (top and bottom), the read path components of one half are utilized for managing the reference generation on the other half. Generating the reference voltage takes place during the read phase, remaining inoperative in idle and write states for power saving and performance efficiency. Furthermore, a charge pump is incorporated into the write peripherals for generating a boosted voltage for the WWL and PB signals for increasing the DRT. The charge pump increases the overall DRT by 100×, while only requiring a 3% area overhead. The macro can work with a single supply and single clock and obtains extended DRT by utilizing an in-macro boosted supply, which enables seamless SoC integration. Although the charge-pump requires an external reference voltage to operate, this supply voltage is not required to deliver power and can be supplied with any DAC or a reference circuit inside the SoC with minimal effort. The memory macro was fabricated in a 65 nm CMOS technology demonstrating the advantages of the novel features presented herein in terms of power and retention time.

It is expected that during the life of a patent maturing from this application many relevant bitcells, gain cells, memory arrays, memory macros, peripheral circuitry, sense amplifiers and switches for memory arrays will be developed and the scope of the terms bitcell, gain cell, memory array, memory macro, peripheral circuitry, sense amplifier, switch and similar terms are intended to include all such new technologies a priori.

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. For example, identifying a fault is described with respect to a plurality of embodiments of the invention. It is appreciated that faults, mode of failures and trends of modes of failures described in specific embodiments may be identified and analyzed as defined in other embodiments described herein. In addition, certain features such as analyzing touchdown, trends or health estimation are described with respect to specific embodiments and may also be provided with respect to other embodiments of the invention although not specifically mentioned with respect to these embodiments. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

Unless otherwise defined, all technical and scientific terms used herein have the same meaning as commonly understood by one of ordinary skill in the art to which this disclosure pertains. In case of conflict, the patent specification, including definitions, will govern.

Although stages of methods according to some embodiments may be described in a specific sequence, methods of the disclosure may include some or all of the described stages carried out in a different order. A method of the disclosure may include a few of the stages described or all of the stages described. No particular stage in a disclosed method is to be considered an essential stage of that method, unless explicitly specified as such.

It is to be understood that the disclosure is not necessarily limited in its application to the details of construction and the arrangement of the components and/or methods set forth herein. Other embodiments may be practiced, and an embodiment may be carried out in various ways.

The phraseology and terminology employed herein are for descriptive purposes and should not be regarded as limiting. Citation or identification of any reference in this application shall not be construed as an admission that such reference is available as prior art to the disclosure. To the extent that section headings are used, they should not be construed as necessarily limiting.

1. A memory array, comprising:
an array comprising a plurality of bitcells arranged in rows and columns, each of said rows storing a respective data word, wherein each of said columns respectively comprises:
a first subset of said bitcells, configured for storing a first subset of data bits, wherein a first read bitline is connected to respective read bitline inputs of said first subset of bitcells;
a second subset of said bitcells, configured for storing a second set of data bits, wherein a second read bitline is connected to respective read bitline inputs of said second subset of bitcells;
a first reference bitcell having a read bitline input connected to said second read bitline and configured for storing a first reference data level; and
a second reference bitcell having a read bitline input connected to said first read bitline and configured for storing a second reference data level,
a first row of switching elements, configured to controllably connect respective first read bitlines of at least two adjacent columns together; and
a second row of switching elements, configured to controllably connect respective second read bitlines of at least two adjacent columns together,
wherein each of said bitcells is further connected to a respective word line configured to trigger a read operation of said respective bitcell, said first reference bitcells of said columns and said second reference bitcells of said columns respectively comprising a first reference bitcell row of said array and a second reference bitcell row of said array, and wherein first reference bitcells and second reference bitcells of a same column store opposite data levels, and said first reference bitcells along said first reference bitcell row store alternating data levels and said second reference bitcells along said second reference bitcell row store alternating data levels.

2. The memory array of claim 1, further comprising a respective sense amplifier for each of said columns, having a first input connected to said first read bitline of said column and a second input connected to said second read bitline of said column, wherein an output of said sense amplifier is indicative of a level of a data bit stored in an addressed bitcell.

3. The memory array of claim 1, wherein respective reference data levels are repeatedly written to the first reference bitcells of said memory array and to the second reference bitcells of the memory array via respective write lines.

4. The memory array of claim 1, further comprising a preset element configured for presetting respective levels of said first read bitlines and said second read bitlines.

5. The memory array of claim 1, wherein for each of said columns the respective first read bitline and the respective second read bitline extend over the entire column, and wherein an unused portion of the respective first read bitline runs parallel to said second subset of said bitcells of said column and an unused portion of the second read bitline runs parallel to said first subset of said bitcells of said column.

6. The memory array of claim 1, wherein the first reference bitcells and the second reference bitcells are located on an axis of symmetry of the memory array.

7. The memory array of claim 1, wherein all of said bitcells in said memory array have a same structure.

8. The memory array of claim 1, wherein said first row of switching elements is controlled by a first control signal generated from an address of an accessed row and said second row of switching elements is controlled by a second control signal having an opposite level to said first control signal, such that said first row of switching elements and said second row of switching elements are closed at opposite times based on said address of said accessed row.

9. A method of accessing a memory array, comprising:
wherein said memory array comprises a plurality of bitcells arranged in rows and columns, each of said rows storing a respective data word, each of said columns respectively comprising:
a first subset of said bitcells, configured for storing a first subset of data bits, wherein a first read bitline is connected to respective read bitline inputs of said first subset of bitcells;
a second subset of said bitcells, configured for storing a second set of data bits, wherein a second read bitline is connected to respective read bitline inputs of said second subset of bitcells;
a first reference bitcell having a read bitline input connected to said second read bitline and configured for storing a first reference data level; and
a second reference bitcell having a read bitline input connected to said first read bitline and configured for storing a second reference data level,
a first row of switching elements, configured to controllably connect respective first read bitlines of at least two adjacent columns together; and
a second row of switching elements, configured to controllably connect respective second read bitlines of at least two adjacent columns together,
wherein each of said bitcells is further connected to a respective word line configured to trigger a read operation of said respective bitcell, said first reference bitcells of said columns and said second reference bitcells of said columns respectively comprising a first reference bitcell row of said array and a second reference bitcell row of said array, and wherein first reference bitcells and second reference bitcells of a same column store opposite data levels, and said first reference bitcells along said first reference bitcell row store alternating data levels and said second reference bitcells along said second reference bitcell row store alternating data levels,
and wherein said accessing said method array comprises:
for a row of said memory array addressed by an address signal:
writing a data word to said addressed row;
writing respective data levels to said first reference bitcells and to said second reference bitcells; and
reading a data level from a bitcell of said array by:
based on a value of a specified bit of said address signal, performing one of:
connecting a read bitline of an addressed bitcell in a row associated with said first subset of bitcells to a first input of a sense amplifier and connecting a read bitline of a second reference bitcell in a same column as said addressed bitcell to a second input of said sense amplifier; and
connecting a read bitline of an addressed bitcell in a row associated with said second subset of bitcells to said second input of a sense amplifier and connecting a read bitline of a first reference bitcell in a same column as said addressed bitcell to said first input of said sense amplifier.

10. The method of claim 9, further comprising determining a data level of said addressed bitcell from an output of said sense amplifier.

11. The method of claim 9, further comprising:
based on said value of said specified bit of said address signal, performing one of:
coupling together read bitlines of said second reference bitcells of a plurality of columns; and
coupling together read bitlines of said first reference bitcells of a plurality of columns.

12. The method of claim 9, wherein said writing respective data levels to said first reference bitcells and to said second reference bitcells is performed during a hold state of operation of said array.

13. The method of claim 9, further comprising establishing a preset level on said read bitlines prior to a read operation.
